(19) United States
(12) Patent Application Publication
(10) Pub. No.: US 2025/0006626 A1
(43) Pub. Date: Jan. 2, 2025

(54) INTEGRATED CIRCUIT WITH SUPERIMPOSED CHIPS AND CAPACITIVE CONNECTION

(71) Applicant: COMMISSARIAT A L'ENERGIE ATOMIQUE ET AUX ENERGIES ALTERNATIVES, PARIS (FR)

(72) Inventors: Didier BELOT, GRENOBLE CEDEX 09 (FR); Hervé BOUTRY, GRENOBLE CEDEX 09 (FR); Jean-Baptiste DORE, GRENOBLE CEDEX 09 (FR); Olivier VALORGE, GRENOBLE CEDEX 09 (FR)

(21) Appl. No.: 18/696,582

(22) PCT Filed: Sep. 27, 2022
(86) PCT No.: PCT/EP2022/076764

§ 371 Date: Mar. 28, 2024

(30) Foreign Application Priority Data
Sep. 28, 2021 (FR) FR2110183

(51) Int. Cl. H01L 23/522; H01L 23/00; H01L 23/66; H01L 25/18

(52) U.S. Cl. CPC H01L 23/5222; H01L 23/66; H01L 24/16; H01L 25/18; H01L 2223/6627; H01L 2223/6677; H01L 2224/16145; H01L 2225/06513; H01L 2924/1205

(57) ABSTRACT

An integrated circuit includes a first chip and a second chip assembled on each other, the first chip being electrically connected to the second chip through a coupling capacitor which is situated in an inter-chip junction zone, between the first chip and the second chip, the coupling capacitor including a first conductive armature, in electrical contact with the first chip, and a second conductive armature in electrical contact with the second chip, at least one part of the first armature being formed by one or more electrically conductive microposts which each extend from the first chip in the direction of the second chip.

### TECHNICAL FIELD

Generally speaking, the technical field is that of microelectronics, in particular that of integrated circuits made in the form of stacks of several chips assembled together and electrically connected together.

### TECHNOLOGICAL BACKGROUND

In the field of microelectronics, it is common to assemble together several chips having different functions, in particular chips obtained by different manufacturing techniques. The integrated circuit thus obtained then has the structure of a three-dimensional stack.

Such a circuit is schematically represented in FIG. 1. This circuit 5 comprises a first chip 10 and a second chip 20, assembled on each other. The first chip is electrically connected to the second chip by means of micropillars 4 which each extend from the first chip to the second chip, through a junction layer 3 (made of oxide or polymer, for example), which binds the chips together. Such a micropillar generally comprises two half-micropillars, i.e. two microposts (one made on the first chip and the other on the second chip) connected to each other by a solder micro-ball (formed, for example, from a tin-based material). Such a micro-pillar has a total height of around ten microns, for example. Such an electrical connection is essentially equivalent to a resistor R in series with an inductance L (the pillar self-inductance; the pillar forms a sort of portion of electrically conductive wire). At high frequencies, the total impedance associated with this connection becomes significant due to this inductive component (as illustrated in FIG. 1), which can hinder transmission of signals from one chip to another by causing undesirable reflections when passing from one chip to another and losses caused by this high impedance.

### SUMMARY

Within this context, there is provided an integrated circuit comprising a first chip and a second chip assembled on each other, the first chip being electrically connected to the second chip by a coupling capacitor which is located in an inter-chip junction zone, between the first chip and the second chip, and which allows high-frequency electrical connection (frequency greater than 10, or even greater than 100 or 300 GHz) between these two chips.

Such a capacitor, with capacitance C, has an impedance which varies as 1(/jC2πf), and which therefore decreases as the frequency f increases, becoming very low at high frequency. It is therefore well adapted to create a connection for the purpose of transmitting a high-frequency electrical signal from one circuit to another. In an integrated circuit, however, overall space is generally a critical issue, so at first sight it might be discouraged from employing such a capacitor, which is by nature of quite large overall size, to make this connection. However, for very high frequencies, for example in the order of a hundred gigahertz or more, even a capacitor with a low electric capacitance (for example in the order of fifty femtofarads), of low overall size, makes it possible to obtain a low connection impedance, for example less than ten Ohms. In other words, in this frequency range, this type of coupling capacitor connection becomes interesting in terms of overall size and integration.

Arranging this capacitor in the inter-chip junction zone moreover makes it possible to advantageously make use of the space available in this interstitial zone, in order to perform there a more sophisticated function than a DC connection or a mechanical connection between chips.

The coupling capacitor in question may comprise:
a first conductive armature, in electrical contact with the first chip, and
a second conductive armature in electrical contact with the second chip,
at least one part of the first armature being facing the second armature, the first and second armatures being electrically insulated from each other,
at least one part of the first armature being formed by one or more electrically conductive microposts, each of which extends from the first chip in the direction of the second chip.

“Micropost» designates an element, for example of cylindrical shape, projecting from the chip considered, extending in the direction of the other chip, but not completely up to the other chip. The dimensions (diameter, height) of such a micropost are typically greater than 1 micron and less than 100 microns, for example between 10 and 50 microns.

“Micropillar” or, equivalently, by “complete micropillar” designates an element which extends from one of the two chips to the other chip, by directly connecting these two chips together. Such a micropillar is formed, for example, by two microposts, one made on the first chip and the other on the second chip, connected to each other by a solder micro-ball.

The microposts and micropillars in question are electrically conductive. They are typically made of one or more metal materials. Each micropost may be in one piece, formed from the same metal material (for example copper or a copper-based alloy), or comprise several portions (several layers) formed by different metal materials.

Furthermore, “armature” designates a typically metal-based, electrically conductive, structure the shape of which may be simple (e.g. in the form of a plate) or more complex. The different elements of the armature are in electrical contact with each other. In other words, “armature” designates one of the two electrodes of the coupling capacitor.

Making one of the capacitor armatures from one or more microposts is particularly interesting. Indeed, making such microposts (which serve as a base for the micropillars mentioned in the section relating to the technological background) is technologically well mastered, particularly in such an inter-chip junction zone. This also makes it possible to bring some portions of the first armature closer to the second armature, to achieve a high capacitance per unit area despite the distance separating both chips in the inter-chip junction zone. Indeed, this distance is typically greater than 5 microns for an assembly between chips using micropillars (due to the dimensions of the micropillars themselves and the solder micro-ball that ensures junction between them). It should also be noted that, in general, in the integrated circuit in question, DC connections between the two chips (conventional connection, by electrical conduction) are made in addition to the high-frequency capacitive connection mentioned above, these DC connections being made by means of one or more complete micropillars. The gap between chips is then quite large (several microns), and it is therefore particularly interesting to bring the two armatures closer together, at least in places, to increase the capacitor capacitance (which is cleverly achieved by using one or more microposts, electrically connected to the first chip, but insulated from the second armature of the capacitor).

In the present application, by chip, it is meant an overall planar structure (the overall shape of which is that of a small plate), based on one or more semiconductor materials (as well as other materials, in particular metal materials and/or electrically insulating oxides), and capable of integrating different active or passive components (transistor, diode, resistor, radiating or guide structure). The chip in question may be formed by a complete (and functionalised) wafer, or by only a portion of such a wafer (i.e. by a die).

The first chip and the second chip are assembled on each other in that they are connected (mechanically connected) to each other, with the second chip located just above the first chip, parallel thereto, virtually against the first chip. In other words, the first chip has a first surface (which delimits the first chip), the second chip has a second surface (which delimits the first chip), and the two chips are assembled in such a way that the first surface extends facing the second surface, in parallel to and at a reduced distance from it (for example with a gap of less than 30 microns). The two chips are thus assembled to each other at these first and second surfaces.

The junction zone mentioned above, which is an inter-chip assembly zone and which constitutes an interstitial zone between chips, is delimited by the first and second surfaces in question.

In practice, the mechanical connection between chips is achieved by adhering some elements of the first chip, which extend into the assembly zone in question (for example microposts), to elements of the second chip (again microposts, for example). An optional filler material, for example a polymer (or an oxide, typically silicon oxide), can fill the unoccupied part of the assembly zone, to obtain a more mechanically robust assembly, forming a inter-chip connection layer.

The assembling technology employed here is typically a micropillar type technology, sometimes called “Copper Pillar bonding” or “Copper Pillar Bump”.

Further to the characteristics set forth above, the device set forth above may have one or more of the following optional characteristics, considered individually or according to any technically contemplatable combinations:
each micropost extends perpendicularly to the first chip, from the first chip to an end face of the micropost;
the second armature comprises, for each micropost, a face or a planar face portion facing and at a reduced distance from the end face of this micropost;
at least one part of the second armature is formed by one or more additional electrically conductive microposts, each of which extends in the direction of the first chip, from the second chip to an end face of the additional micropost;
each micropost, as well as each additional micropost, is laterally delimited by a side surface, and at least some of the additional microposts are laterally offset with respect to said microposts, their respective side surfaces each being facing the side surface of one of said microposts; this arrangement contributes to increasing the capacitor capacitance; it also allows quite large tolerances in terms of lateral alignment between chips;
at least some of said additional microposts are sandwiched between microposts of the first armature; this makes it possible to increase the area density of microposts and the capacitor capacitance;
at least some of the additional microposts each extend facing one of said microposts, the end face of the additional micropost considered being facing and at a reduced distance from the end face of the corresponding micropost, by being electrically insulated from the end face of this micropost;
the second armature comprises a planar plate which extends facing said micropost or microposts;
the second armature is free of microposts; this arrangement facilitates manufacture;
said microposts are arranged periodically by forming a regular array;
at least one part of the first armature is separated from the second armature by a distance of less than 2 microns, or even less than 0.5 micron;
the coupling capacitor has an average electric capacitance per unit area greater than or equal to 5 picofarads per square millimetre;
the coupling capacitor has an electric capacitance greater than or equal to 50 femtofarads;
the first chip is at least partly, or even mainly, formed by a first type of semiconductor material, while the second chip is at least partly, or even mainly, formed by a second type of semiconductor material different from the first type of semiconductor material; the first type of material is, for example, silicon; the second type of material is, for example, a type III-V semiconductor; in the field of microelectronics, the type of semiconductor material and the manufacturing technologies used can be quite different depending on the type of function to be performed; assembling two chips made from different types of semiconductor material therefore makes it possible to integrate quite different functions into this same circuit;
the first plate of the coupling capacitor is electrically connected, for example through an electrical conductor, to a first electronic component of the transistor, diode, amplifier, antenna, waveguide or filter type, while its second armature is electrically connected, for example through an electrical conductor, to a second electronic component of the transistor, diode, amplifier, antenna, waveguide or filter type;
the first electronic component is configured to generate, emit, transmit or filter an electrical signal at a frequency greater than or equal to 10 GHz, or even greater than 100 or even 300 GHz, or even more (the spectrum of the signal in question may, for example, extend up to 325 GHz);
the first electronic component and/or the second electronic component is an active component (electrically powered).

The present technology and its different applications will be better understood upon reading the following description and upon examining the accompanying figures.

### BRIEF DESCRIPTION OF THE FIGURES

The figures are set forth by way of indicating and in no way limiting purposes.

FIG. 1 schematically represents an integrated circuit with superimposed chips of prior art.

FIG. 2 schematically represents an integrated circuit according to a first embodiment, comprising two chips assembled on each other and electrically connected to each other through a coupling capacitor.

FIG. 3 schematically represents the integrated circuit of FIG. 2, in a side view.

FIG. 4 schematically represents a set of microposts of the coupling capacitor in question, in a top view.

FIG. 5 schematically represents the coupling capacitor, in a perspective view.

FIG. 6 shows the integrated circuit of FIGS. 2 and 3 in the form of an equivalent electrical diagram.

FIG. 7 represents, in the form of an equivalent electrical diagram, an integrated circuit according to a second embodiment, also comprising two chips assembled on each other and connected through a coupling capacitor.

FIG. 8 schematically represents an integrated circuit according to a third embodiment, also comprising two chips assembled on each other and connected through a coupling capacitor with microposts.

FIG. 9 schematically represents an integrated circuit according to a fourth embodiment, also comprising two chips assembled on each other and connected through a coupling capacitor with microposts.

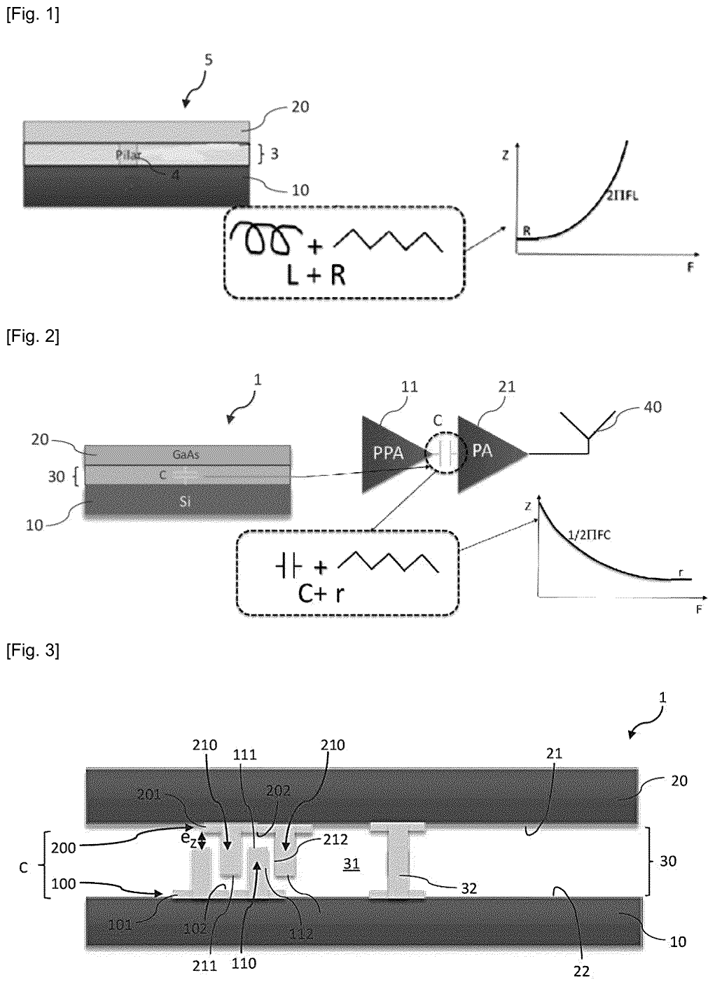

### DETAILED DESCRIPTION

One example of an integrated circuit 1 with stacked chips connected through the particular type of capacitive connection set forth above is schematically represented in FIG. 2. In this example, the circuit is intended to emit a very high frequency signal, herein at a frequency f greater than 100 GHz, and even greater than 300 GHz.

It comprises a first chip 10, here based on silicon, and a second chip 20, here based on gallium arsenide GaAs (more generally, based on a type III-V semiconductor, i.e. comprising an element from column V of the periodic table of the elements, for example nitrogen N or phosphorus P, associated with one or more elements from column III of the periodic table of the elements, for example gallium Ga, aluminium Al and/or indium In). The first chip 10, based on silicon, is a support well adapted to make one or more components enabling frequency of the signals to be increased, and enabling a very high frequency signal to be generated. Here, for example, the first chip 10 comprises a pre-power amplifier (PPA) 11, which delivers a signal (for example as an electric voltage) at the frequency f mentioned above.

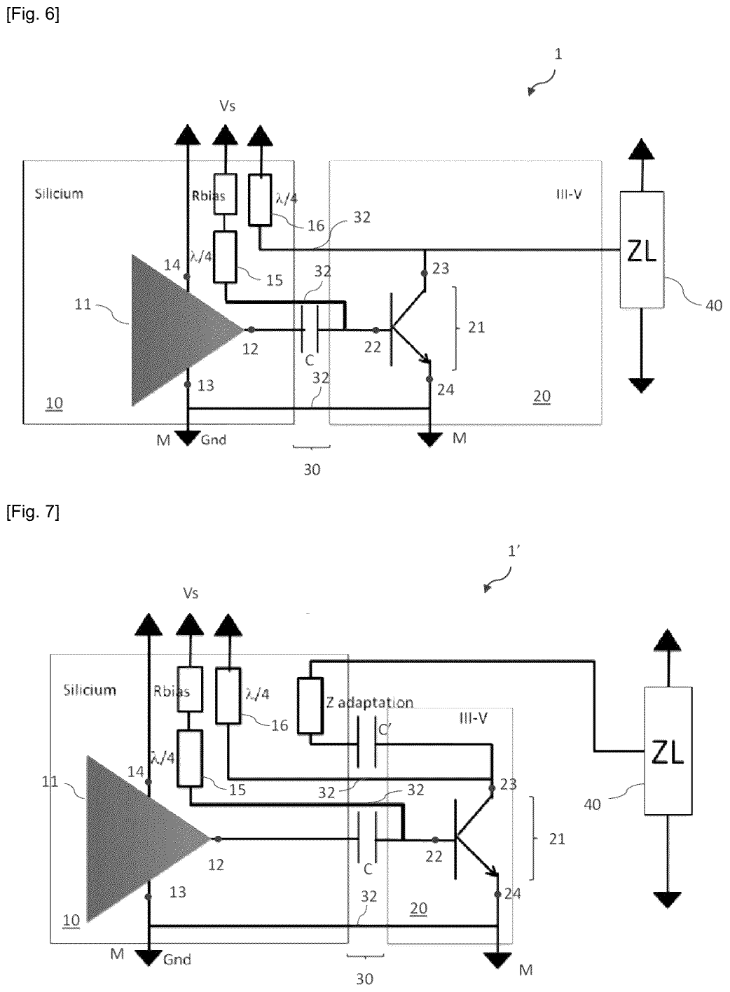

As for the second chip 20, it constitutes a support well adapted to make one or more components enabling power amplification at these very high frequencies, before emitting the signal thus amplified, by means of a radiating antenna 40. Here, the second chip 20 incorporates a power amplifier (PA) 21 adapted to these frequencies, made for example in the form of a transistor (see FIG. 6).

The first chip 10 and the second chip 20 are assembled on each other, in parallel to each other, to form a three-dimensional stack. The first chip 10 has a first surface 11 (upper surface of the first chip, here), and the second chip 20 has a second surface 21 (lower surface of the second chip, here), in front of the first surface 11. The two chips are thus assembled together with their surfaces 11 and 21 facing each other.

The first surface 11 more precisely corresponds to the free surface of the first chip 10 before assembly, not including the microposts and assembly structure. It is a planar surface (herein, it is the mean plane of the free surface that the chip 10 has before assembly). Similarly, the second surface 21 is the free surface of the second chip before assembly 20, excluding the microposts and assembly structure.

An inter-chip junction zone, 30, extends from the first surface 11 to the second surface 21. This junction zone, which is an inter-chip assembly zone, comprises inter-chip connection elements enabling them to be secured to each other. These connection elements comprise complete micropillars, 32, which extend from the first chip 10 to the second chip 20 (and which are each formed by two microposts connected, for example, through a solder micro-ball). An optional filler material 31 (generally called “underfill” in this technical field), for example polymer-based, can fill the unoccupied part of the assembly zone 30 to obtain a more mechanically robust assembly.

The complete micropillars 32 also make it possible to electrically connect the first chip 10 to the second chip 20 in order to transmit from one chip to the other supply voltages or currents for electronic components (see FIGS. 6 and 7), or DC or low-frequency (with a frequency much lower than 100, or even 10 or even 1 GHz) signals. Indeed, here, each of the micropillars 32 is conductive, thus enabling electrical conduction from one chip to the other.

The first chip 10 is also connected to the second chip 20 through a coupling capacitor, C, located in the junction zone 30. This capacitor here connects the preamplifier 11 of the first chip to the power amplifier 21 of the second chip 20, in order to transfer the very high frequency signal mentioned above from one chip to the other.

For this capacitive connection, it is desired to obtain an impedance Z that is small compared with the characteristic impedance of the transmission lines, which is 50 Ohms here. This makes it possible to limit return loss R_{L} (loss due to reflection on the capacitive connection). Table 1 below gathers some values of the impedance Z associated with such a capacitive connection, at a frequency of 300 GHz, for different values of the capacitance of the coupling capacitor C. In this table, the return loss is expressed in decibels, i.e. R_{L}(dB)=20 log [((50+Z)−50)/(50+Z+50)], Z being expressed in Ohms.

TABLE 1

| C (fF) | Z @ 300 GHz (Ohms) | R_{L} (dB) |
|---|---|---|
| 50 | 10.6 | −20 |
| 100 | 5.3 | −26 |
| 200 | 2.6 | −32 |
| 500 | 1 | −40 |

As illustrated by these values, if return loss of less than 20 decibels is desired (Z less than approximately 10 Ohms), it is desirable for the capacitance of the coupling capacitor C to be greater than 50 fF. Furthermore, in terms of overall size, an occupied surface area of less than 100×100 μm² is generally desirable for such a component. The desired capacitance per unit area is therefore typically greater than or equal to 5 pF/mm².

As will be seen below, such values can actually be obtained by making this coupling capacitor from armatures provided with microposts, for dimensional parameters that are realistic for this type of technology. The coupling capacitor C employed in this example is now described in more detail, with reference to FIGS. 3 to 5.

This capacitor comprises:
a first conductive armature, 100, in electrical contact with the first chip 10 (more precisely, here, in electrical contact with an output terminal 12 of the preamplifier 11), and
a second conductive armature 200, in electrical contact with the second chip 20 (more precisely, here, in electrical contact with an input terminal 22, for example a gate, of the power amplifier 21).

The first and second armatures are electrically insulated from each other, i.e. they are separated from each other by an insulator (whether air or a solid insulating material such as the polymer-based filler material 31 mentioned above).

The first armature 100 comprises a first conductive plate 101, for example made of metal (sometimes called a “pad” in this technical field), which extends in parallel to the first surface 11, against the first chip 10, for example against the first surface 11, or possibly slightly recessed with respect thereto. The first armature 100 also comprises conductive microposts, 110, which extend from the first plate 101, in the direction of the second chip 20 (see FIGS. 3 and 5).

Similarly, the second armature 200 comprises a second conductive plate 201, or “pad”, which extends in parallel to the second surface 21, against the second chip 20, for example against the second surface 21 (or possibly slightly recessed with respect thereto). The first armature 200 itself also comprises conductive microposts, 210, which extend from the second plate 201, in the direction of the first chip 10.

In this first embodiment, the microposts 210 of the second armature are laterally offset with respect to the microposts 110 of the first armature and extend almost up to the first plate 101, whereas the microposts 110 of the first armature extend almost up to the second plate 201. The microposts 110 and 210 are thus sandwiched with each other, with their respective side surfaces facing each other. This arrangement makes it possible to increase the surface area over which the two armatures are in electrical contact with each other, by also making use of the side surfaces 112, 212 of the microposts 110, 210. Stated differently, this makes it possible to increase the effective surface area of the capacitor C, and therefore its electric capacitance.

As can be seen in FIG. 3, each micropost 110 extends from the first plate 101, in the direction of the second chip, to an end face 111. The axis of the micropost is perpendicular to the first chip, while its end face 111 is parallel to the first chip. The end face 111 of the micropost is located at a reduced distance from the second plate 201 (herein, at a small distance compared to the thickness of the junction zone 30). This distance, noted e_{z}, is for example less than 2 or even 0.5 micron. It may, for example, be between 0.1 and 0.5 micron. For each micropost 110, the end face 111 of the micropost thus extends facing and at a reduced distance from a planar portion 202 of the second armature, more precisely in front of a small portion of the second plate 201 of this armature.

In the same way, each micropost 210 extends from the second plate 201, in the direction of the first chip 10, to an end face 211 of the micropost. The axis of the micropost is perpendicular to the second chip, while its end face 211 is parallel to the second chip. The end face 211 of the micropost is located at a reduced distance from the first plate 101. This distance is, for example, less than 2 or even 0.5 micron (it may, for example, be between 0.1 and 0.5 micron). It may be equal to the distance e_{z} mentioned above. For each micropost 210, the end face 211 of the micropost thus extends facing and at a reduced distance from a planar portion 102 of the first armature, more precisely in front of a small portion of the first plate 101 of this armature.

As indicated above, for each micropost 110, part of the side surface 112 of the micropost 110 is facing the side surface 212 of one of the microposts 210, the microposts 110 and 210 being sandwiched with one another.

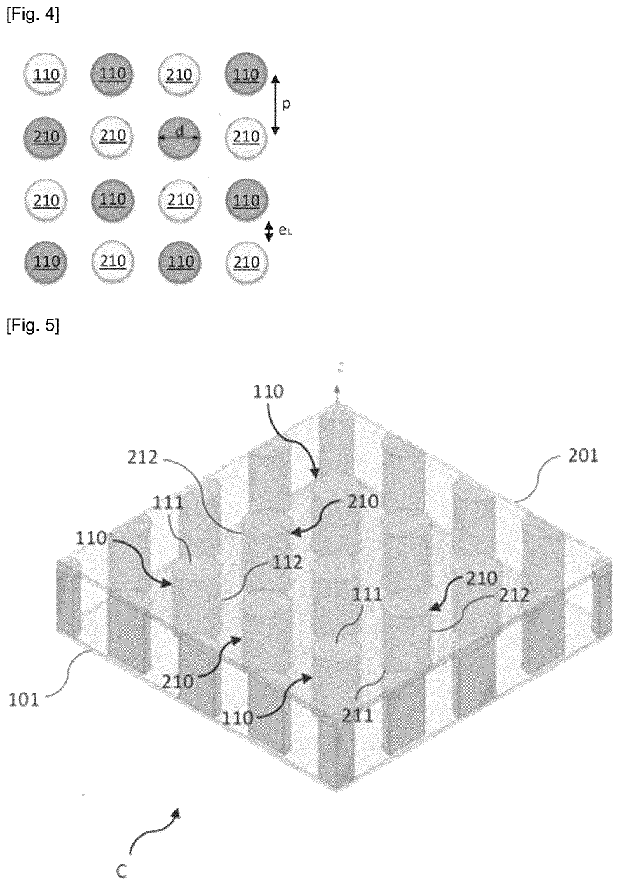

Here, the microposts 110 of the first armature are periodically distributed over the first plate 101 by forming a regular two-dimensional array. Herein, this array has a staggered pattern (a pattern that is repeated periodically), i.e. a square pattern with a micropost 110 at each vertex of the square and a further micropost 110 in the centre of the square (FIGS. 4 and 5).

The microposts 210 of the second armature are themselves also periodically distributed, on the second plate 201, by forming a regular two-dimensional array, herein an array identical to that of the first armature. These two arrays are laterally offset from each other so that they interlock with each other. The assembly comprising the microposts 110 and 210 then forms a square array, with a pitch p, with alternating microposts 110 and microposts 210. Stated differently, in each row and in each column of this array of microposts, there is a micropost 110, then a micropost 210, then a micropost 110, and so on. Each micropost 210, except those located at the corners of the array, is thus sandwiched between several microposts 110.

The microposts 110 and 210 are cylindrical here, with a diameter d. From a lateral point of view, they are therefore separated two by two by a distance e_{L} equal to p-d.

A numerical simulation has been carried out to determine capacitance of the capacitor C for this geometry of the armatures, in a case where (FIG. 5):
the diameter d of the microposts is 10 microns whereas their height is 15 microns,
the pitch p is 20 microns,
the gap e_{z} is 1 micron, and where
each armature forms a square with sides of 80 microns (therefore with eight microposts per armature, and sixteen microposts in all).

When the armatures are separated by air (relative permittivity εᵣ=1), the capacitance of the capacitor is then estimated to be 23 femtofarad (fF), or 3.6 picoFarad per mm² (3.6 pF/mm²). And when the space between the armatures is filled with a filler polymer such as polyimide (for which the relative permittivity εᵣ is approximately 3.5 at the frequencies considered), the capacitance of the capacitor is then estimated to be 80 femtofarad (fF), i.e. 12.5 pF per mm².

The examples of values given above for the dimensions of the microposts and their spacing are typical of this type of assembly technology (moreover these dimensions can be slightly smaller). It is therefore noticed from this example that this type of capacitor structure effectively makes it possible to obtain a capacitance per unit area suitable for the intended application, typically greater than 5, and even 10 pF/mm², for realistic dimensions in terms of manufacture.

In terms of dimensions, micropillars used to make this capacitive connection may have a diameter d of between 10 and 50 microns, and a height also of between 10 and 50 microns. The lateral spacing e_{L} between micropillars can in turn be between d and twice d. The micropillars can be distributed with an area density of between 5% and 25%, for example. This area density is equal to the cross-sectional area of a micropillar, multiplied by the number N of micropillars considered and divided by the total surface area over which these N micropillars are distributed (surface area occupied by these N micropillars). By way of example, for a square array with a pitch p=2.d (i.e. e_{L}=d, which corresponds to the type of structure whose manufacture is well mastered in practice), this area density is 20%.

It may be noted, in terms of manufacture, that this type of structure allows quite large tolerances in terms of alignment of the two chips with each other. Indeed, if both chips are laterally offset with respect to each other, with respect to the configuration set forth above (i.e.: if each micropost 210 is not exactly positioned in the middle, between two microposts 110), the capacitance value obtained will nevertheless remain close to that corresponding to perfect alignment (stated differently, the value of this capacitance is relatively insensitive to lateral alignment errors between chips). Indeed, in the event of an alignment error, each micropost 210 would be a little closer to one of the microposts 110 (which would tend to increase the value of the capacitance), but, as compensation, it would also be a little further from the other micropost 110 which flanks it (which would, on the contrary, tend to decrease the capacitance in question, at least partly compensating for the increase in question, and limiting the variation in capacitance due to this misalignment).

Different alternatives can be made to the capacitor C of this first embodiment, for example by resorting to another type of two-dimensional array, based on another pattern (for example a triangular pattern), or by using another arrangement of the microposts, for example an overall concentric or spiral arrangement. Furthermore, as mentioned above, smaller dimensions than those of the numerical example described above are contemplatable, in particular for the gap e_{z} (which would lead to larger capacitance values than in the numerical example in question).

FIG. 6 schematically represents the integrated circuit 1 of FIG. 2, in the form of an equivalent electrical diagram.

As can be seen in this figure, an electric supply voltage Vs is applied to a supply terminal 13 of the preamplifier 11 of the first chip, while the electrical ground M of the circuit is connected to a ground terminal 14 of the preamplifier. The output terminal 12 of the preamplifier 11, for its part, is connected to the first armature 100 of the coupling capacitor C, via a line or track having, for example, a line impedance of 50 Ohms.

On the other side of the junction zone 30, the second armature 200 of the coupling capacitor C is connected to the input terminal 22 of the power amplifier 21 (via a line having an impedance of 50 Ohms). This input terminal in fact corresponds to the gate of the transistor which here forms this amplifier. The source 24 of this transistor is connected to ground M, herein by being connected to the ground of the first chip via a complete micropillar 32 (DC micropillar) passing through the junction zone 30. The drain 23 of transistor 21 is in turn connected to a radiating antenna 40 to emit the very high frequency signal thus amplified.

The transistor is biased by the supply voltage Vs. More precisely, the voltage Vs is applied to the drain 23, while a voltage, reduced by an adjustment resistor R_{bias}, is applied to the gate 22. For this, the drain 23 and gate 22 are each connected to a supply voltage source, located on the first chip (and which delivers the voltage Vs), through the complete micropillars 32 (DC micropillars) passing through the junction zone 30. To prevent the very high frequency signals produced by the preamplifier 11 and the power amplifier 21 from travelling up the DC power supply lines, a quarter-wavelength line 15, 16 is connected between the micropillar 32 considered and the power supply voltage source in question, for each of these two micropillars 32. Each quarter-wavelength line 15, 16 is a portion of transmission line having a length equal to λ/4, where λ is the wavelength of the signal in question.

FIG. 7 represents, in the form of an equivalent electrical circuit, an integrated circuit 1′ according to a second embodiment. The integrated circuit 1′ is identical to the integrated circuit 1 of the first embodiment (represented in FIGS. 2 to 6), except that the amplified signal produced by the power amplifier passes back through the first chip 10 before being transmitted to the radiating antenna 40. For this, an additional coupling capacitor, C′, is connected to the drain 23 of the power amplifier transistor. This coupling capacitor C′ is identical, or at least similar, to the coupling capacitor C set forth above. The drain 23 is therefore connected to a second armature of this capacitor (via a 50 Ohm line), while the first armature of this capacitor is connected to the radiating antenna 40 via an impedance Z, made on the first chip 10, and enabling impedance matching with the antenna. The elements of circuit 1′ which are identical, or at least correspond to those of circuit 1, bear the same references as for circuit 1 of the first embodiment.

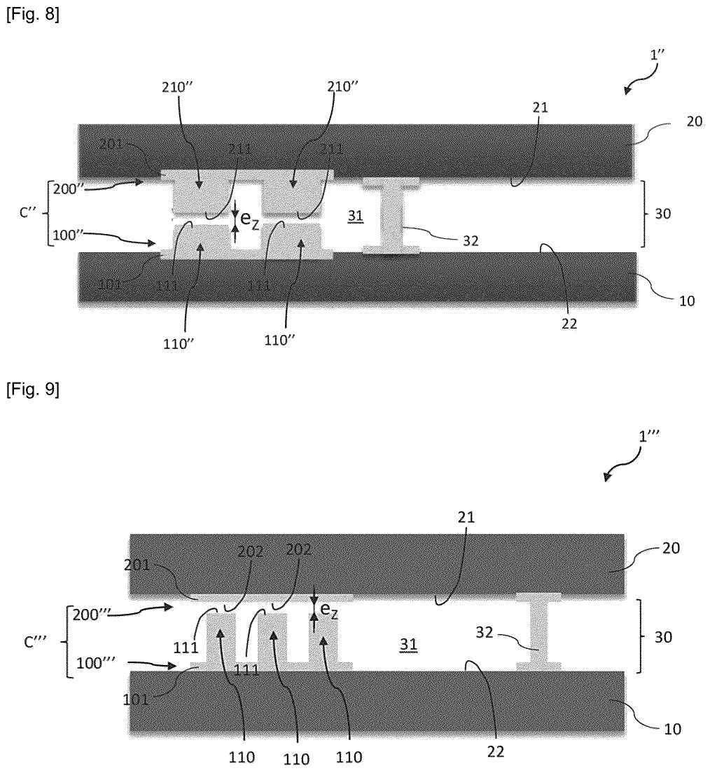

Other ways of making a coupling capacitor between chips from one or more microposts, different from that of the first embodiment, can be contemplated, as can be seen in FIGS. 8 and 9.

FIG. 8 thus represents an integrated circuit 1″ according to a third embodiment, similar to the circuit 1 of the first embodiment, but in which the microposts 210″ of the second armature 200″ extend in line with the microposts 110″ of the first armature 100″, instead of being laterally offset with respect thereto.

For the rest, the integrated circuit 1″ is identical, or at least essentially identical, to the integrated circuit 1 of the first embodiment. Identical elements of these two embodiments are moreover identified by the same reference numbers.

The coupling capacitor C″ of the integrated circuit 1″ comprises, as before, a first armature 100″ in electrical contact with the first chip 10, and a second armature 200″ in electrical contact with the second chip 20. The first armature and the second armature respectively comprise a first plate 101 and a second plate 201, as set forth above. In addition, they each comprise one or more, in this case several, microposts 110″, 210″.

As indicated above, the microposts 210″ extend in line with the microposts 110″, i.e. by being aligned with the microposts 110″ along a direction perpendicular to the chips. The microposts 210″ and the microposts 110″ each have a height close to half the thickness of the junction zone 30, and slightly less than this half-thickness (whereas in the first embodiment, the microposts 110 and 210 each had a height close to the thickness of the junction zone). Each pair of microposts, gathering one of the microposts 110″ and the micropost 210″ facing it, thus forms a sort of complete micropillar, but without a solder micro-ball between both microposts 110″ and 210″.

Each micropost 110″ extends from the first plate 101, in the direction of the second chip 20, to an end face 111 parallel to the first chip. Similarly, each micropost 210″ extends from the second plate 201, in the direction of the first chip 10, to an end face 211 parallel to the second chip. For each pair of microposts 110″ and 210″ facing each other, the respective end faces 111 and 211 of the two microposts are facing and at a reduced distance from each other. They are parallel to each other. Here, they are completely superimposed on each other. The gap e_{z} separating them is less than 2 microns, or even 0.5 micron. It can, for example, be between 0.1 and 0.5 micron.

For microposts with a diameter of 10 microns and a gap e_{z} of 1 micron, an elementary electric capacitance of approximately 2.4 fF is obtained for each pair of microposts 110″, 210″ (using, by way of example, polyimide as the filler material). Twenty or more microposts are then required on each armature (to obtain twenty or more pairs 110″/210″) to obtain a total electric capacitance greater than or equal to 50 fF, for the coupling capacitor C″. Assuming that the microposts are arranged in a square array with a pitch of 20 microns, a capacitance per unit area of approximately 6 pF/mm² is thus achieved, which is within the desired range. Here again, therefore, it is noticed that this type of capacitor structure makes it possible to obtain a capacitance per unit area suitable for the intended application (typically greater than 5 pF/mm²) for realistic dimensions in terms of manufacture, especially as the gap e_{z} could have a value of less than 1 micron, in practice.

FIG. 9 represents an integrated circuit 1′″ according to a fourth embodiment. This integrated circuit 1′″ is similar to the circuit 1 of the first embodiment, but it comprises a coupling capacitor C′″ whose second armature is free of micropost. For the rest, the integrated circuit 1′″ is identical, or at least essentially identical, to the integrated circuit 1 of the first embodiment. The identical elements of these two embodiments are identified by the same reference numbers.

The coupling capacitor C′″ of the integrated circuit 1′″ comprises, as previously, a first armature 100′″ in electrical contact with the first chip 10, and a second armature 200′″ in electrical contact with the second chip 20. The first armature and the second armature respectively comprise a first plate 101 and a second plate 201 as set forth above. Furthermore, the first armature 100′″ comprises at least one, in this case several, microposts 110. On the other hand, the second armature 200′″ is free of microposts.

The microposts 110 of the first armature extend in the direction of the second chip 20, from the first plate 101 to an end face 111 parallel to the first chip, and parallel to the second plate 201. For each micropost 110, the end face 111 of the micropost thus extends facing and at a reduced distance from a planar portion 202 of the second armature 200″, more precisely in front of a small portion of the second plate 201. This distance is again noted e_{z}. It is, for example, less than 2 microns, or even less than 0.5 micron (it may, for example, be between 0.1 and 0.5 micron).

The distribution of the microposts 110 on the first plate 101 may be different from the distribution of the microposts 110 set forth above for the first embodiment. In particular, the area density of microposts 110 may be greater than in the first embodiment (since there are no microposts belonging to the second electrode to be sandwiched between the microposts 110 of the first electrode).

Various alternatives can be made to the integrated circuits just set forth, in addition to those already mentioned.

For example, the two chips could be made from the same type of semiconductor material (e.g. silicon) instead of from two different types of material. In addition, the integrated circuit could comprise one or more other chips, assembled to the two aforementioned chips to form a more complete three-dimensional stack (these other chips could also be connected to the rest of the circuit via one or more coupling capacitors, made in an inter-chip assembly zone).

Furthermore, the coupling capacitor mentioned above could be used to connect together components other than those mentioned above, and functions other than the amplification functions set forth above could be implemented in such an integrated circuit.

1. An integrated circuit comprising a first chip and a second chip assembled one on each other, the first chip being electrically connected to the second chip through a coupling capacitor which is located in an inter-chip junction zone between the first chip and the second chip, the coupling capacitor comprising:
a first conductive armature in electrical contact with the first chip, and
a second conductive armature in electrical contact with the second chip,
at least one part of the first armature being facing the second armature, the first and second armatures being electrically insulated from each other,
at least one part of the first armature being formed by one or more electrically conductive microposts which each extend from the first chip in the direction of the second chip;
in which integrated circuit:
the first armature of the coupling capacitor is electrically connected to a first electronic component of the transistor, diode, amplifier, antenna, waveguide or filter type, configured to generate, emit, transmit or filter an electrical signal having a frequency greater than or equal to 10 GHz, or even 300 GHz;
the second armature is electrically connected to a second electronic component of the transistor, diode, amplifier, antenna, waveguide or filter type.

2. The integrated circuit according to claim 1, wherein:
each micropost extends perpendicularly to the first chip, from the first chip to an end face of the micropost,
the second armature has, for each micropost, a face or a planar face portion facing and at a reduced distance from the end face of this micropost.

3. The integrated circuit according to claim 1, wherein at least one part of the second armature is formed by one or more additional electrically conductive microposts, which each extend in the direction of the first chip, from the second chip to an end face of the additional micropost.

4. The integrated circuit according to claim 3, wherein each micropost, as well as each additional micropost, is laterally delimited by a side surface, and wherein at least some of the additional microposts are laterally offset with respect to said microposts, their respective side surfaces each being facing the side surface of one of said microposts.

5. The integrated circuit according to claim 4, wherein at least some of said additional microposts are sandwiched between microposts of the first armature.

6. The integrated circuit according to claim 1, wherein at least some of the additional microposts each extend facing one of said microposts, the end face of the additional micropost considered being facing and at a reduced distance from an end face of the corresponding micropost, by being electrically insulated from the end face of this micropost.

7. The integrated circuit according to claim 2, wherein the second armature is free of micropost.

8. Integrated circuit according to claim 1, wherein said microposts are arranged periodically by forming a regular array.

9. The integrated circuit according to claim 1, wherein at least one part of the first armature is separated from the second armature by a distance of less than 2 microns, or even less than 0.5 micron.

10. The integrated circuit according to claim 1, wherein the coupling capacitor has an average electric capacitance per unit area greater than or equal to 5 picofarads per square millimetre.

11. The integrated circuit according to claim 1, wherein the coupling capacitor has an electric capacitance greater than or equal to 50 femtofarads.

12. The integrated circuit according to claim 1, wherein the first chip is at least partly formed by a first type of semiconductor material while the second chip is at least partly formed by a second type of semiconductor material different from the first type of semiconductor material.
